(19) United States
(12) Patent Application Publication
(10) Pub. No.: US 2025/0391726 A1
(43) Pub. Date: Dec. 25, 2025

(54) SEMICONDUCTOR PACKAGE AND METHOD FOR FORMING THE SAME

(71) Applicant: Taiwan Semiconductor Manufacturing Co., Ltd., Hsinchu (TW)

(72) Inventors: Yu-Jen Lien, Tainan (TW); Cheng-Chieh Hsieh, Tainan (TW); Li Wang, Hsinchu (TW); Shih-Chang Ku, Taipei City (TW); Chen-Hua Yu, Hsinchu (TW)

(21) Appl. No.: 18/750,566

(22) Filed: Jun. 21, 2024

(51) Int. Cl. H01L 23/367; H01L 23/00; H01L 23/31; H01L 23/498; H01L 25/065

(52) U.S. Cl. CPC H01L 23/3672; H01L 23/3128; H01L 23/49816; H01L 24/05; H01L 24/13; H01L 25/0652; H01L 2224/05009; H01L 2224/05025; H01L 2224/13007; H01L 2224/13025; H01L 2924/1431; H01L 2924/1434; H01L 2924/15311; H01L 2924/182; H01L 2924/351

(57) ABSTRACT

A semiconductor package includes a first integrated circuit device, wherein the first integrated circuit device comprises a semiconductor substrate and an interconnect structure disposed over a first surface of the semiconductor substrate, wherein the semiconductor substrate comprises pillars protruding from a second surface of the semiconductor substrate. The package also include a heat sink disposed over the first integrated circuit device, wherein the heat sink, and the pillars, enclose a space, and a liquid metal disposed in a space between the pillars.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are a cross-sectional view and a plan view of an integrated circuit device, in accordance with some embodiments.

FIGS. 2-3 are cross-sectional views of intermediate stages in the manufacturing of an integrated circuit device, in accordance with some embodiments.

FIGS. 4-16 are cross-sectional views of intermediate stages in the manufacturing of a semiconductor package, in accordance with some embodiments.

FIGS. 17-18 are cross-sectional views of a semiconductor package, in accordance with some embodiments.

FIGS. 19A and 19B are a cross-sectional view and a plan view of a semiconductor package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a semiconductor package includes a liquid metal disposed over integrated circuit devices for dissipating heat. In some embodiments, the integrated circuit device also includes pillars of high aspect ratio at its back side, for providing a large contact area with the liquid metal. As such, the large contact area and the excellent thermal conductivity of the liquid metal may provide the semiconductor package with improved thermal dissipation performance. The semiconductor package may also include designs for preventing or managing the leakage of the liquid metal.

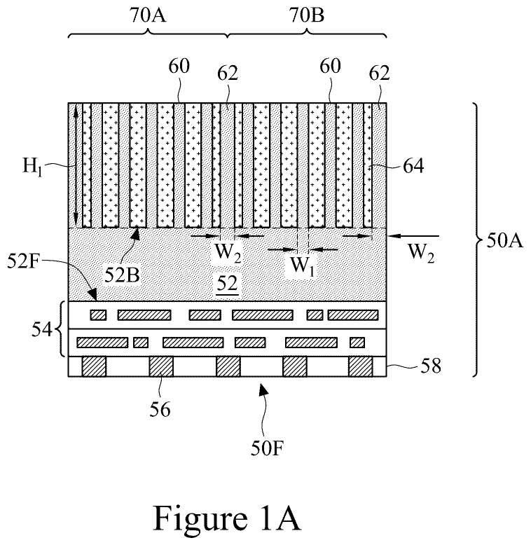

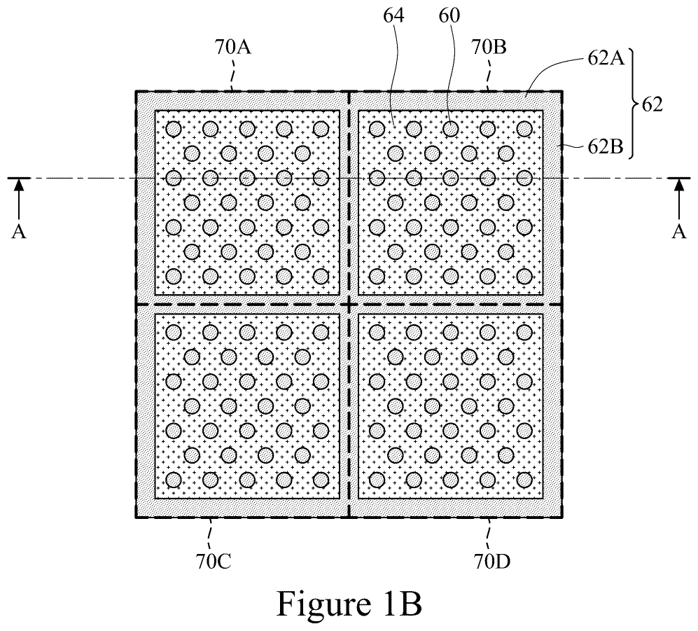

FIGS. 1A and 1B are a cross-sectional view and a plan view of an integrated circuit device, respectively, wherein FIG. 1A is taken along the A-A line in FIG. 1B, in accordance with some embodiments. FIG. 1A is a cross-sectional view of a first integrated circuit device 50A. One or more first integrated circuit devices 50A will be packaged in subsequent processing to form semiconductor packages. Each first integrated circuit device 50A may be a logic die (e.g., central processing unit (CPU), graphics processing unit (GPU), microcontroller, etc.), a memory die (e.g., dynamic random access memory (DRAM) die, static random access memory (SRAM) die, hybrid memory cube (HMC) module, a high bandwidth memory (HBM) module, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), an application-specific integrated circuit (ASIC) die, the like, or combinations thereof (e.g., a system-on-a-chip (SoC) die).

The first integrated circuit device 50A includes a semiconductor substrate 52, an interconnect structure 54, die connectors 56, and a dielectric layer 58 (if present). The semiconductor substrate 52 may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has a first surface 52F (e.g., the surface facing downward in FIG. 1A), which is an active surface. Devices are at the active surface of the semiconductor substrate 52. The devices may be active devices (e.g., transistors, diodes, etc.) and/or passive devices (e.g., capacitors, resistors, etc.).

The interconnect structure 54 is on the active surface of the semiconductor substrate 52, and it is used to electrically connect the devices of the semiconductor substrate 52 to form an integrated circuit. The interconnect structure 54 may include one or more dielectric layer(s) and respective one or more metallization layer(s) in the dielectric layer(s). Acceptable dielectric materials for the dielectric layers include an oxide, a nitride, a carbide, or a combination thereof. For example, the dielectric material may include silicon oxide, aluminum oxide, silicon nitride, silicon oxynitride, silicon carbide, silicon oxycarbide, silicon carbonitride, silicon oxycarbonitride, a combination thereof, or the like. Other dielectric materials may also be used, such as a polymer including polybenzoxazole (PBO), polyimide, benzocyclobuten (BCB), or the like. The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The interconnect structure 54 may be formed by a damascene process, such as a single damascene process, a dual damascene process, or the like.

Die connectors 56 are at the front side 50F of the first integrated circuit device 50A. The die connectors 56 may be conductive pillars, pads, or the like, to which external connections are made. The die connectors 56 are in and/or on the interconnect structure 54. For example, the die connectors 56 may be part of an upper metallization layer of the interconnect structure 54. The die connectors 56 can be formed of a metal, such as copper, aluminum, or the like, and can be formed by, for example, plating, or the like.

A dielectric layer 58 is optionally disposed at the front side 50F of the integrated circuit device 50. The dielectric layer 58 is in and/or on the interconnect structure 54. For example, the dielectric layer 58 may be an upper dielectric layer of the interconnect structure 54. The dielectric layer 58 laterally encapsulates the die connectors 56. The dielectric layer 58 may be an oxide, a nitride, a carbide, a polymer, the like, or a combination thereof. The dielectric layer 58 may be formed, for example, by spin coating, lamination, chemical vapor deposition (CVD), or the like. Initially, the dielectric layer 58 may bury the die connectors 56, such that the top surface of the dielectric layer 58 is above the top surfaces of the die connectors 56. The die connectors 56 are exposed through the dielectric layer 58 during the formation of the integrated circuit device 50. Exposing the die connectors 56 may remove any solder regions that may be present on the die connectors 56. A removal process can be applied to the various layers to remove excess materials over the die connectors 56. The removal process may be a planarization process such as a chemical mechanical polish (CMP), an etch-back, combinations thereof, or the like. After the planarization process, top surfaces of the die connectors 56 and the dielectric layer 58 are coplanar (within process variations) and are exposed at the front side 50F of the first integrated circuit device 50A.

In some embodiments, the first integrated circuit device 50A includes pillars 60 and ribs 62, and dummy features 64 at a back side of the semiconductor substrate 52. The pillars 60 and the ribs 62 may be a part of the semiconductor substrate 52. For example, the pillars 60 and ribs 62 may protrude over a second surface 52B of the semiconductor substrate 52, where the second surface 52B is opposite to the first surface 52F of the semiconductor substrate 52. The dummy features 64 may be disposed over the second surface 52B and between the pillars 60, between the ribs 62, and between adjacent ones of the pillar 60 and the rib 62. The dummy features 64 may cover sidewalls of the pillars 60 and the ribs 62. In some embodiments, the dummy features 64 may include a material that can be removed by a suitable solvent or by a suitable etching process. In subsequent packaging processes, the dummy features 64 will be removed, and the space occupied by the dummy features 64 will be filled with liquid metal for conducting heat generated from the first integrated circuit device 50A away. In some embodiments, the dummy features 64 include a polymer material, such as epoxy, polyacrlates, polyimide, a combination thereof, or the like.

In some embodiments, the ribs 62 include first ribs 62A extending along a first direction and second ribs 62B extending along a second direction. The first ribs 62A and the second ribs 62B may intersect each other. In some embodiments, the ribs 62 include a ring shape as outer embankments at the back side of the semiconductor substrate 52 in a plan view. The ribs 62 may also include a cross shape within the ring shape that divides the back-side of the semiconductor substrate 52 into sub-regions 70A-70D. The ribs 62 may be embankments of the sub-regions 70A-70D. Although four sub-regions 70A-70D are illustrated in FIG. 1B, the first integrated circuit device 50A may include more or less sub-regions divided by the ribs 62. In some embodiments, each of the sub-regions 70A-70D includes one or more pillars 60.

The pillars 60 may include a circular shape in the plan view illustrated in FIG. 1B. In some embodiments, the pillars 60 include other suitable shapes, such as an oval shape, a rectangular shape, or a square shape. In some embodiments, the pillars 60 have a first width W₁ and the ribs 62 include a second width W₂. The second width W₂ may be greater than the first width W₁. In some embodiments, the pillars 60 and the ribs 62 have a height (or depth) H₁ in a range from about 50 μm to about 600 μm. While the pillars 60 having a large height (e.g., H₁) can provide a large surface area, the ribs 62 around the pillars 60 can enhance the structural robustness of the semiconductor substrate 52. In some embodiments, the pillars 60 and the ribs 62 have straight sidewalls substantially perpendicular or inclined with respect to the first surface 52F of the semiconductor substrate 52 in the cross-sectional view, although the pillars 60 and/or the ribs 62 can have curved sidewalls. In some embodiments, the dummy features 64 have a top surface coplanar with top surfaces of the pillars 60 and top surfaces of the ribs 62. The dummy features 64 may be exposed from the semiconductor substrate 52.

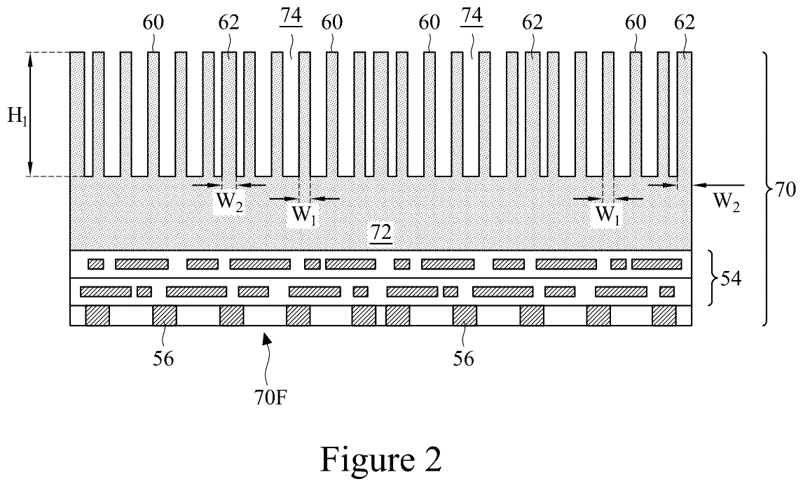

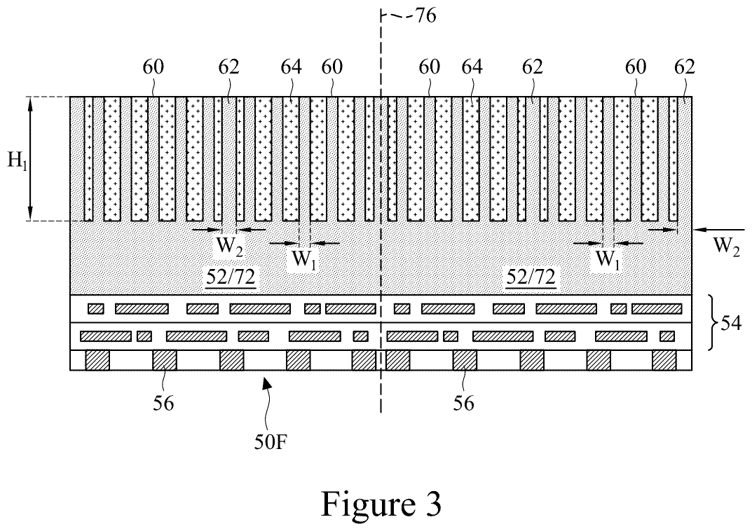

FIGS. 2-3 are cross-sectional views illustrating an exemplary flow of forming the first integrated circuit device 50A described for FIG. 1A, in accordance with some embodiments. In FIG. 2, an integrated circuit device 70 including a substrate 72 is provided. The substrate 72 may be a wafer form of the semiconductor substrate 52 as described for FIG. 1 and will be singulated to become a plurality of the semiconductor substrates 52 as illustrated in FIG. 1A in subsequent processing. The interconnect structure 54, and the die connectors 56 are formed at the front side 50F of the integrated circuit device 70 and will be singulated together with the semiconductor substrate 72.

Referring to FIG. 2, a plurality of trenches 74 is formed in the substrate 72, in accordance with some embodiments. The trenches 74 may have the same pattern as the dummy features 64. The formation of the trenches 74 may include forming a patterned mask (not shown), such as a hard mask that includes patterns of the trenches 74, on the substrate 72, and etching the substrate 72 according to the patterns of the patterned mask. The etching process may include a dry etching such as reactive ion etching (RIE) or the like. After the trenches 74 are formed, the patterned mask may be removed by any acceptable removable process, such as a wet etching or a dry etching.

In FIG. 3, the trenches 74 are filled to form a plurality of the dummy features 64 in substrate 72 in accordance with some embodiments. In some embodiments, the dummy features 64 are formed by chemical vapor deposition (CVD), spin coating, lamination, or the like. An as-formed material of the dummy features 64 may fill the trenches 74 and have an excess portion (not shown) over the substrate 72. A planarization process, such as chemical mechanical polishing (CMP) or mechanical grinding, may be performed to remove the excess portion of the material of the dummy features 64 over the substrate 72, leaving the dummy features 64 embedded in the substrate 72 and exposed from the substrate 72.

After the dummy features 64 are formed, singulation of the integrated circuit device 70 is performed along the scribe line 76 to form individual structures, such as the first integrated circuit device 50A illustrated in FIG. 1A. FIG. 3 illustrates a single scribe line 76 to form two first integrated circuit devices 50A for illustrative purposes, and embodiments may include any number of scribe lines to form more individual structures such as those illustrated in FIG. 1A.

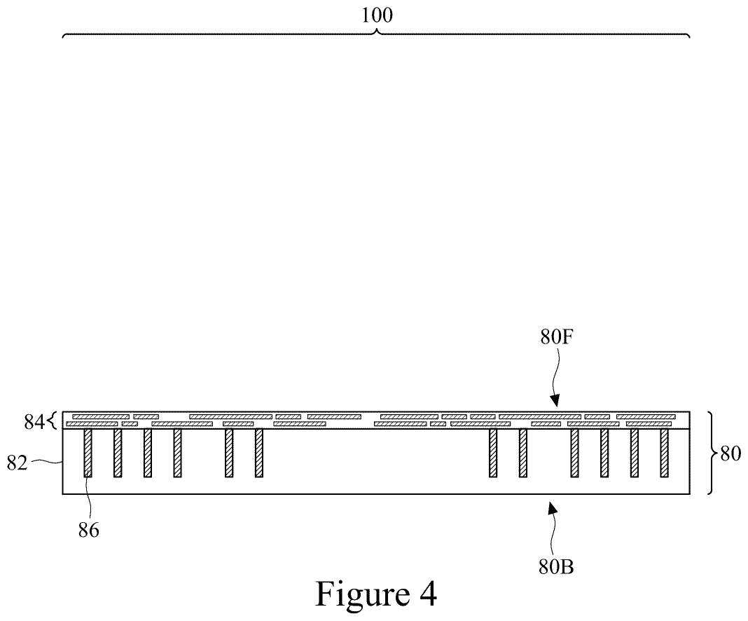

FIGS. 4 to 16 are cross-sectional views of intermediate stages in the manufacturing of a semiconductor package 100 including the first integrated circuit device 50A, in accordance with some embodiments. Referring to FIG. 4, an interposer 80 is shown. The interposer 80 may be a wafer, and a plurality of the first integrated circuit devices 50A may be attached to the interposer 80 using chip-on-wafer (CoW) techniques and later singulated to form individual packages. It is also appreciated that the embodiments illustrated in this disclosure may also be applied to various types of 3DIC packages.

In FIG. 4, the interposer 80 is obtained or formed. In some embodiments, the interposer 80 includes a substrate 82, an interconnect structure 84, and through vias 86. The substrate 82 may be a bulk semiconductor substrate, a semiconductor-on-insulator (SOI) substrate, a multi-layered semiconductor substrate, or the like. The substrate 82 may include a semiconductor material, such as silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The substrate 82 may be doped or undoped. In some embodiments, the substrate 82 does not include active devices therein, although the interposers may include passive devices formed in and/or on a front surface (e.g., 80F) of the substrate 82.

The interconnect structure 84 is over the front surface of the substrate 82, and is used to electrically connect the devices (if any) of the substrate 82 and/or the devices attached to the interposer 80. The interconnect structure 84 may include one or more dielectric layer(s) and respective metallization layer(s) in the dielectric layer(s). Acceptable dielectric materials for the dielectric layers include an oxide, a nitride, a carbide, a combination thereof, or the like. For example, the dielectric material may include silicon oxide, aluminum oxide, silicon nitride, silicon oxynitride, silicon carbide, silicon oxycarbide, silicon carbonitride, silicon oxycarbonitride, a combination thereof, or the like. Other dielectric materials may also be used, such as a polymer including polybenzoxazole (PBO), polyimide, benzocyclobutene (BCB), or the like. The metallization layer(s) may include conductive vias and/or conductive lines to interconnect any devices together and/or to an external device. The metallization layer(s) may be formed of a conductive material, such as a metal, which may be copper, cobalt, aluminum, gold, combinations thereof, or the like. The interconnect structure 84 may be formed by a damascene process, such as a single damascene process, a dual damascene process, or the like.

In some embodiments, die connectors and a dielectric layer (not separately illustrated) are at the front side 80F of the interposer 80. Specifically, the interposer 80 may include die connectors and a dielectric layer that are similar to those of the first integrated circuit device 50A described for FIG. 1A. For example, the die connectors and the dielectric layer may be part of an upper metallization layer of the interconnect structure 84.

The through vias 86 extend into the interconnect structure 84 and/or the substrate 82. The through vias 86 are electrically connected to metallization layer(s) of the interconnect structure 84. As an example to form the through vias 86, recesses can be formed in the interconnect structure 84 and/or the substrate 82 by, for example, etching, milling, laser techniques, a combination thereof, and/or the like. A thin dielectric material may be formed in the recesses, such as by using an oxidation technique. A thin barrier layer may be conformally deposited in the openings, such as by CVD, atomic layer deposition (ALD), physical vapor deposition (PVD), thermal oxidation, a combination thereof, and/or the like. The barrier layer may be formed of an oxide, a nitride, a carbide, combinations thereof, or the like. A conductive material may be deposited over the barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer are removed from a surface of the interconnect structure 84 or the substrate 82 by, for example, a CMP. Remaining portions of the barrier layer and conductive material form the through vias 86.

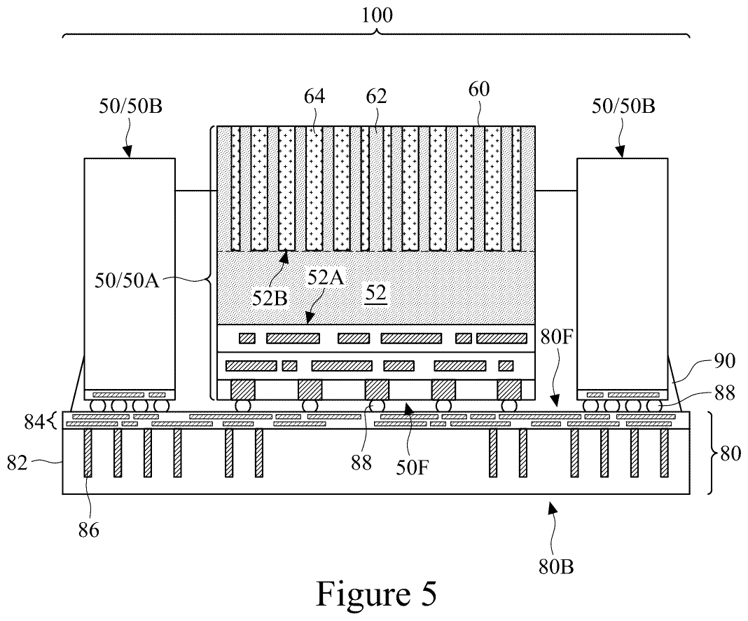

FIG. 5 illustrates one or more integrated circuit devices attached to the interposer 80 in accordance with some embodiments. In the example illustrated in FIG. 5, one integrated circuit device such as the first integrated circuit device 50A illustrated in FIG. 1A and two second integrated circuit devices 50B are attached to the interposer 80, wherein the second integrated circuit devices 50B and the first integrated circuit device 50A are collectively referred to as integrated circuit devices 50. The second integrated circuit devices 50B may be logic dies or memory dies, similar to the first integrated circuit device 50A described for FIG. 1A. In some embodiments, the second integrated circuit devices 50B are stacks of logic dies or memory dies. The first integrated circuit device 50A may have a different function than the second integrated circuit devices 50B. For example, the first integrated circuit device may be a logic die (e.g., GPU), and the second integrated circuit devices 50B may be stacks of memory dies. The first integrated circuit device 50A and the second integrated circuit devices 50B may be formed in processes of a same technology node, or may be formed in processes of different technology nodes. For example, the first integrated circuit device 50A may be of a more advanced process node than the second integrated circuit devices 50B. In some embodiments, the first integrated circuit device 50A consumes more power and/or generates more heat than the second integrated circuit device 50B at a unit time. In some embodiments, the first integrated circuit device 50A is a GPU or CPU, and the second integrated circuit devices 50B are memory stacks.

In FIG. 5, the integrated circuit devices 50 are attached to the interposer 80 with conductive connectors 88, such as solder bonds. The integrated circuit devices 50 may be placed on the interconnect structure 84 using, e.g., a pick-and-place tool. The conductive connectors 88 may be formed of a reflowable conductive material, such as solder, and may further include other conductive materials such as copper, aluminum, gold, nickel, silver, palladium, tin, lead, the like, or a combination thereof. In some embodiments, the conductive connectors 88 are formed by initially forming a layer of solder through methods such as evaporation, electroplating, printing, solder transfer, ball placement, or the like. Once a layer of solder has been formed on the interposer 80, a reflow may be performed in order to shape the conductive connectors 88 into desired bump shapes. Attaching the integrated circuit devices 50 to the interposer 80 may include placing the integrated circuit devices 50 on the interposer 80 and reflowing the conductive connectors 88. The conductive connectors 88 form joints between corresponding die connectors of the interposer 80 and the integrated circuit devices 50, electrically connecting the interposer 80 to the integrated circuit devices 50.

An underfill 90 may be formed around the conductive connectors 88, and between the interposer 80 and the integrated circuit devices 50. The underfill 90 may reduce stress and protect the joints resulting from the reflowing of the conductive connectors 88. The underfill 90 may be formed of an underfill material such as an epoxy, or the like. The underfill 90 may be formed by a capillary flow process after the integrated circuit devices 50 are attached to the interposer 80, or may be formed by a suitable deposition method before the integrated circuit devices 50 are attached to the interposer 80. The underfill 90 may be applied in liquid or semi-liquid form and then subsequently cured. The underfill 90 may have various heights, depending on the distances between the first integrated circuit device 50A and the second integrated circuit devices 50B. In some embodiments, the underfill 90 has a top surface higher than a bottom surface of the dummy features 64 (e.g., second surface 52B of the semiconductor substrate 52). In some embodiments not shown in the figures, the underfill 90 has a top surface level with or lower than the bottom surface of the dummy features 64.

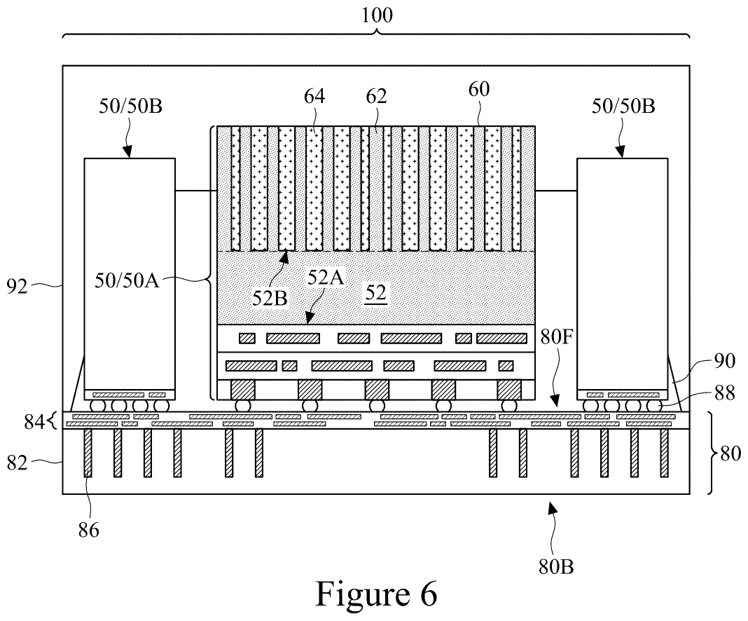

In FIG. 6, an encapsulant 92 is formed over the interposer 80 and the various components on the interposer 80. After formation, the encapsulant 92 encapsulates the integrated circuit devices 50 and the underfill 90. The encapsulant 92 may be a molding compound, which may be a polymer, a resin, an epoxy, or the like, and filler particles in the base material. The filler particles may be dielectric particles of SiO₂, Al₂O₃, or the like, and may have spherical shapes. Also, the spherical filler particles may have a plurality of different diameters. The encapsulant 92 may be applied by compression molding, transfer molding, or the like, and is formed over the interposer 80 such that the integrated circuit devices 50 are buried or covered. The encapsulant 92 may be applied in liquid or semi-liquid form and then subsequently cured.

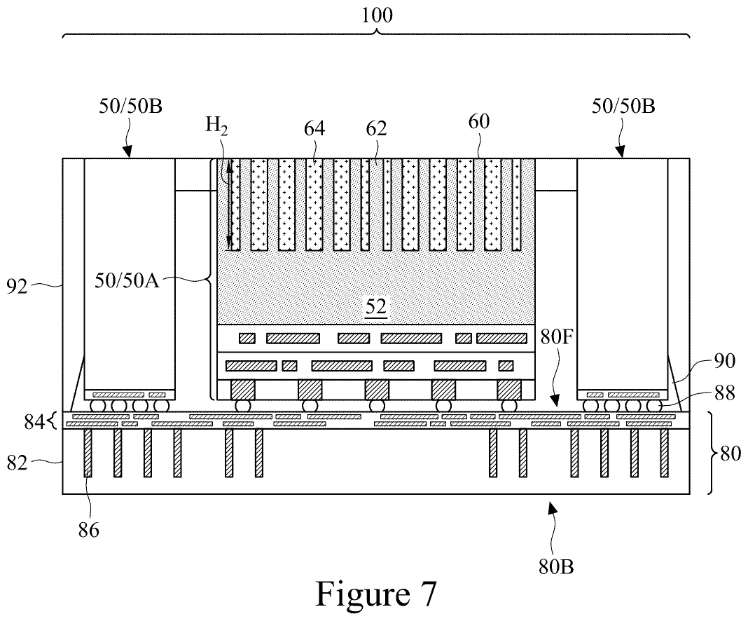

In FIG. 7, the encapsulant 92 is thinned to expose the first integrated circuit device 50A. In some embodiments, the second integrated circuit devices 50B may also be exposed, as illustrated in FIG. 7. Specifically, the thinning removes the portions of the encapsulant 92 right above the first integrated circuit device 50A, thereby exposing the dummy features 64. In some embodiments, the thinning also includes removing a portion of the second integrated circuit devices 50B and/or a portion of the semiconductor substrate 52 (including the pillars 60 and ribs 62) of the first integrated circuit device 50A. A portion of the dummy features 64 may also be removed while removing a portion of the semiconductor substrate 52 of the first integrated circuit device 50A. After the thinning process, the top surfaces of the pillars 60 and ribs 62 (e.g., surface facing away from the interposer 80) and the top surfaces of the dummy features 64 (e.g., surface facing away from interposer 80) are coplanar (within process variations) with the top surface of the encapsulant 92 (e.g., surface facing away from the interposer 80). Additionally, the top surfaces of pillars 60 and the top surfaces of ribs 62 are coplanar (within process variations) with surfaces of one or more second integrated circuit devices 50B. In some embodiments, the pillars 60 and the ribs 62 have a height H2. After thinning, a ratio of the height H2 to the width W1 may be from 1 to 30. The thinning process may be a grinding process, a chemical-mechanical polish (CMP), an etch-back, combinations thereof, or the like.

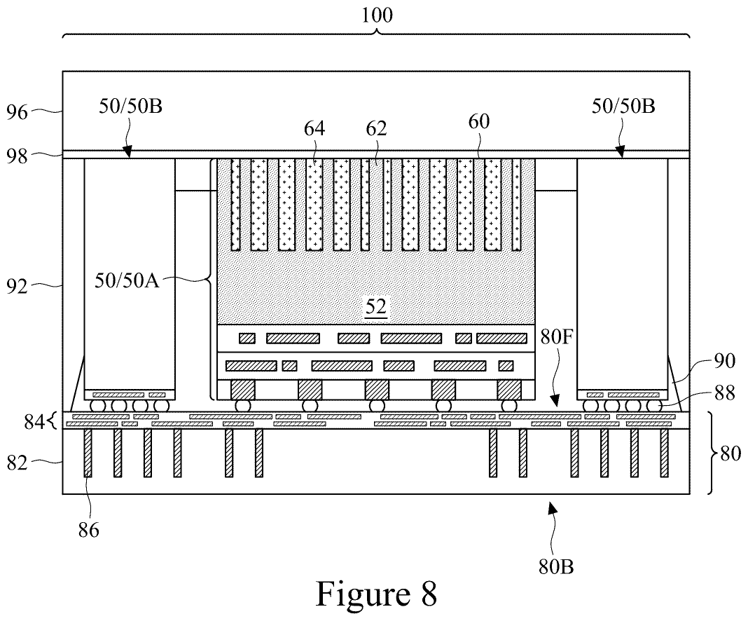

In FIG. 8, the intermediate structure may be placed on a carrier substrate 96 or other suitable support structure for subsequent processing. For example, the carrier substrate 96 may be attached to the first integrated circuit device 50A, the second integrated circuit devices 50B, and the encapsulant 92 by a release layer 98. In some embodiments, the carrier substrate 96 is a substrate such as a bulk semiconductor or a glass substrate having a wafer or panel shape or the like. The release layer 98 may be formed of a polymer-based material, which may be removed along with the carrier substrate 96 from the structure after processing. In some embodiments, the release layer 98 is an epoxy-based thermal-release material, which loses its adhesive property when heated, such as a light-to-heat-conversion (LTHC) release coating.

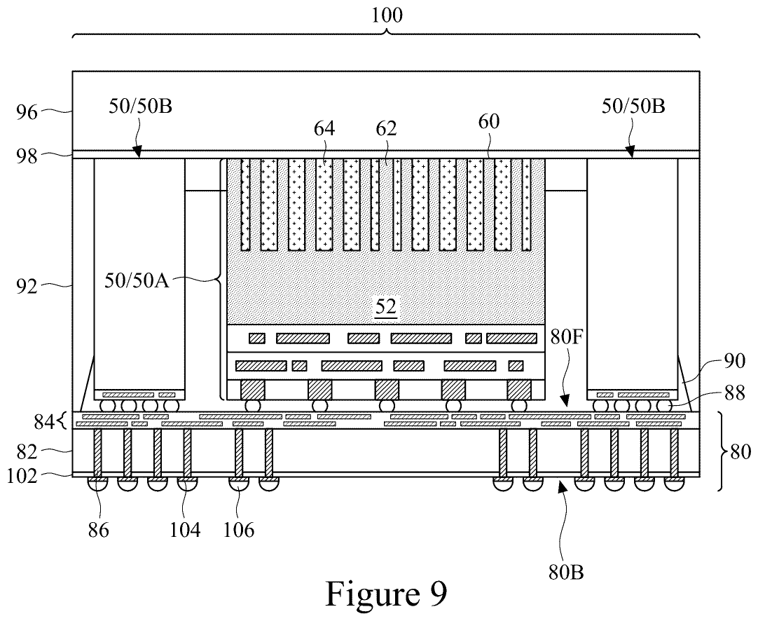

In FIG. 9, the interposer 80 is thinned to expose the through vias 86. Exposure of the through vias 86 may be accomplished by a thinning process, such as a grinding process, a chemical-mechanical polish (CMP), an etch-back, combinations thereof, or the like. In the illustrated embodiment, a recessing process is performed to recess the back surface of the substrate 82 such that the through vias 86 protrude at the back side 80B of the interposer 80. The recessing process may be, e.g., a suitable etch-back process, chemical-mechanical polish (CMP), or the like. In some embodiments, the thinning process for exposing the through vias 86 includes a CMP, and the through vias 86 protrude at the back side 80B of the interposer 80 as a result of dishing that occurs during the CMP or a separate recess etch process. An insulating layer 102 is optionally formed on the back surface of the substrate 82, surrounding the protruding portions of the through vias 86. In some embodiments, the insulating layer 102 is formed of a silicon-containing insulator, such as silicon nitride, silicon oxide, silicon oxynitride, or the like, and may be formed by a suitable deposition method such as spin coating, CVD, plasma-enhanced CVD (PECVD), high-density plasma CVD (HDP-CVD), or the like. Initially, the insulating layer 102 may bury the through vias 86. A removal process can be applied to the various layers to remove excess materials over the through vias 86. The removal process may be a planarization process such as a chemical mechanical polish (CMP), an etch-back, combinations thereof, or the like. After planarization, the exposed surfaces of the through vias 86 and the insulating layer 102 are coplanar (within process variations) and are exposed at the back side 80B of the interposer 80. In another embodiment, the insulating layer 102 is omitted, and the exposed surfaces of the substrate 82 and the through vias 86 are coplanar (within process variations).

Under bump metallurgies (UBMs) 104 may be formed on the exposed surfaces of the through vias 86 and the insulating layer 102 (or the substrate 82, when the insulating layer 102 is omitted). As an example to form the UBMs 104, a seed layer (not separately illustrated) is formed over the exposed surfaces of the through vias 86 and the insulating layer 102 (if present) or the substrate 82. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the UBMs 104. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the UBMs 104.

Further, conductive connectors 106 are formed on the UBMs 104. The conductive connectors 106 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 106 may be formed of a conductive material that is reflowable, such as solder, copper, aluminum, gold, nickel, silver, palladium, tin, the like, or a combination thereof. In some embodiments, the conductive connectors 106 are formed by initially forming a layer of solder through evaporation, electroplating, printing, solder transfer, ball placement, or the like. Once a layer of solder has been formed on the structure, a reflow may be performed in order to shape the material into desired bump shapes. In some embodiments, the conductive connectors 106 comprise metal pillars (such as copper pillars) formed by sputtering, printing, electroplating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

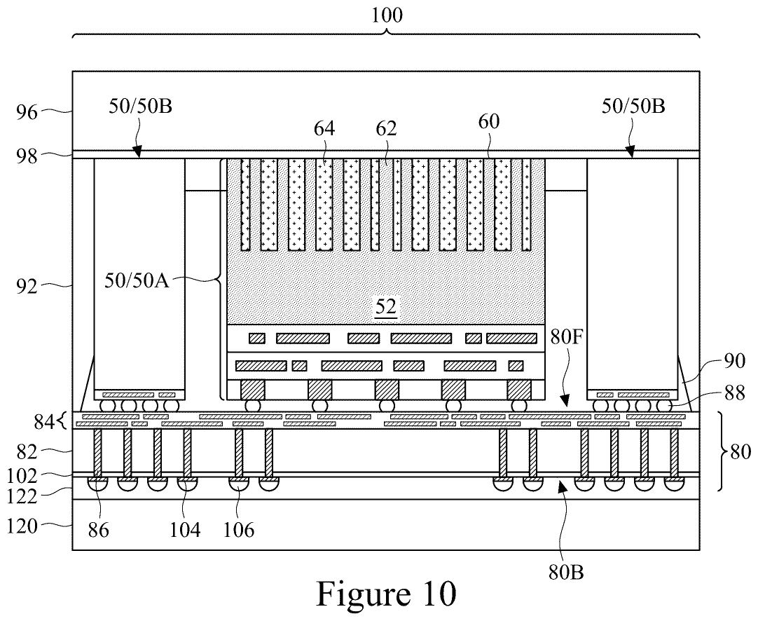

In FIG. 10, the intermediate structure is placed on a carrier substrate 120 or other suitable support structure for subsequent processing. For example, the carrier substrate 120 may be attached to the conductive connectors 106 and a back side 80B of the interposer 80 by a release layer 122. For example, the release layer 122 may have a thickness greater than the conductive connectors 106 to avoid the conductive connectors 106 from touching the carrier substrate 120, which may reduce damage to the conductive connectors 106. The release layer 122 may have a similar material as the release layer 98, such as a thermal-release material, which may lose its adhesive property when heated, such as LTHC release coating. In some embodiments, the carrier substrate 120 is a bulk semiconductor substrate or a glass substrate having a wafer or panel shape or the like.

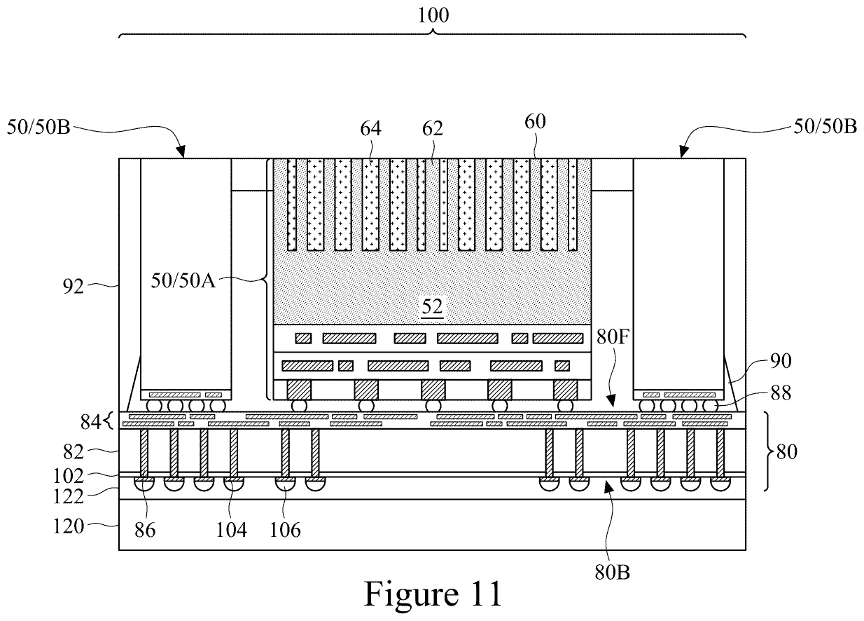

In FIG. 11, a carrier debonding process is performed to detach (debond) the carrier substrate 96 (see FIG. 10) from the first integrated circuit device 50A, the second integrated circuit devices 50B, and the encapsulant 92, thereby exposing the dummy features 64. The debonding includes projecting a light such as a laser light or an ultraviolet (UV) light from a top side of the carrier substrate 96 for heating the release layer 98 locally. Accordingly, the release layer 98 may be decomposed under the locally distributed heat of the light, and the carrier substrate 96 can be removed, while the release layer 122 on the back side 80B of the interposer 80 may not be affected.

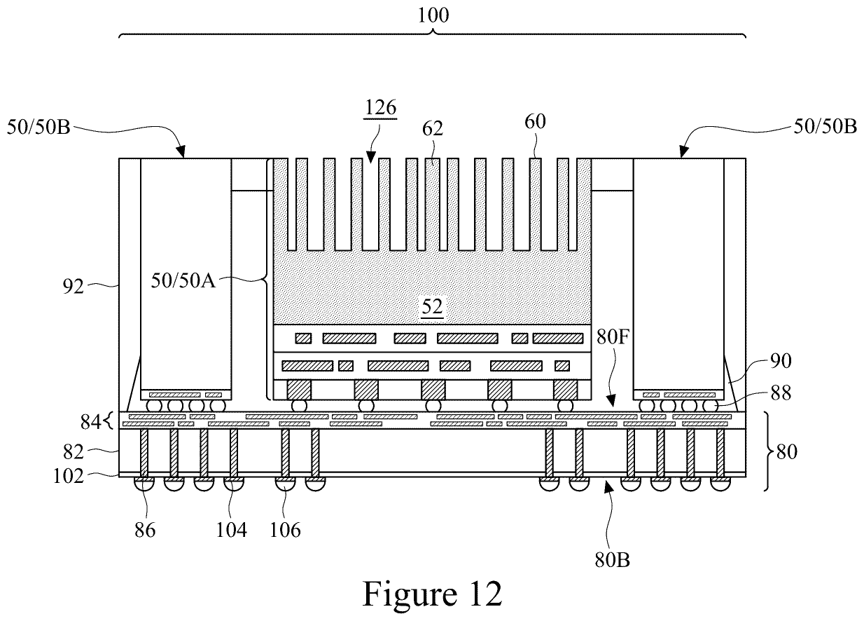

In FIG. 12, the dummy features 64 embedded in the semiconductor substrate 52 of the first integrated circuit device 50A are removed, thereby forming channels 126 between the pillars 60 and ribs 62 of the first integrated circuit device 50A in accordance with some embodiments. The channels 126 have a shape corresponding to those of the dummy features 64. In some embodiments, the dummy features 64 are removed by a suitable extracting process or a suitable etching process.

The processes discussed above may be performed at the wafer level, wherein the interposer 80 is wafer sized, and a singulation process is performed. For example, a carrier debonding is performed to detach (debond) the carrier substrate 120 (see FIG. 11) from the back side 80B of the interposer 80, and a singulation process is performed by cutting along scribe line regions (not shown). In some embodiments, the carrier debonding includes projecting a light such as a laser light or a UV light for heating the release layer 122. Accordingly, the release layer 122 may be decomposed under the heat of the light, and the carrier substrate 120 can be removed. The singulation process includes placing the intermediate structure on a tape (not shown), and a singulation process is performed by cutting along scribe line regions (not shown). The singulation process may include sawing, dicing, or the like. For example, the singulation process can include sawing the insulating layer 102, the encapsulant 92, the interconnect structure 84, and the substrate 82. The singulation process singulates the wafer-sized interposer 80 into individual packages. As a result of the singulation process, the outer sidewalls of the interposer 80 and the encapsulant 92 are laterally coterminous (within process variations).

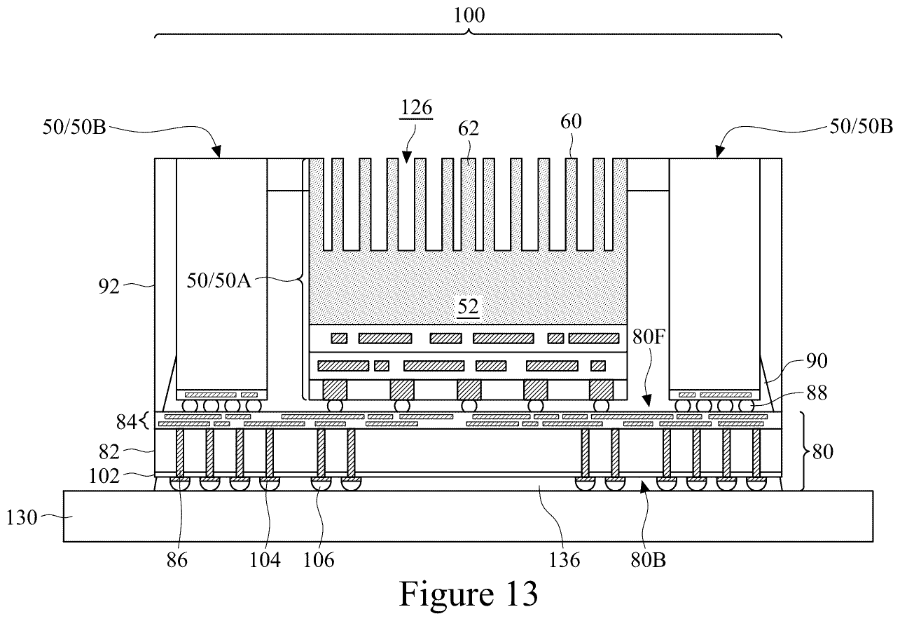

Also referring to FIG. 13, one or more of the singulated packages is attached to a substrate 130 using the conductive connectors 106. The substrate 130 may be an interposer, a core substrate, a coreless substrate, a printed circuit board (PCB), a package substrate, or the like. The substrate 130 may include active and/or passive devices (not separately illustrated). Devices such as transistors, capacitors, resistors, combinations thereof, and the like may be used to generate the structural and functional requirements of the design for the system. The devices may be formed using any suitable methods.

The substrate 130 may also include metallization layers and vias and bond pads over the metallization layers and vias. The conductive connectors 106 may comprise solder reflowed to attach the UBMs 104 to the bond pads of the substrate 130. The conductive connectors 106 electrically connect the metallization layers of the interconnect structure 84 of the interposer 80 to the substrate 130, including metallization layers in the substrate 130. Thus, the substrate 130 is electrically connected to the integrated circuit devices 50. In some embodiments, passive devices (e.g., surface mount devices (SMDs), not separately illustrated) may be attached to the back side 80B of the interposer 80 (e.g., bonded to the UBMs 104) prior to mounting on the substrate 130. In such embodiments, the passive devices may be bonded to a same surface of the substrate 130 as the conductive connectors 106.

In some embodiments, an underfill 136 is formed between the interposer 80 and the substrate 130, surrounding the conductive connectors 106 and the UBMs 104. The underfill 136 may be formed by a capillary flow process after substrate 130 is attached or may be formed by a suitable deposition method before the substrate 130 is attached. The underfill 136 may be a continuous material extending from the substrate 130 to the interposer 80 (e.g., the insulating layer 102).

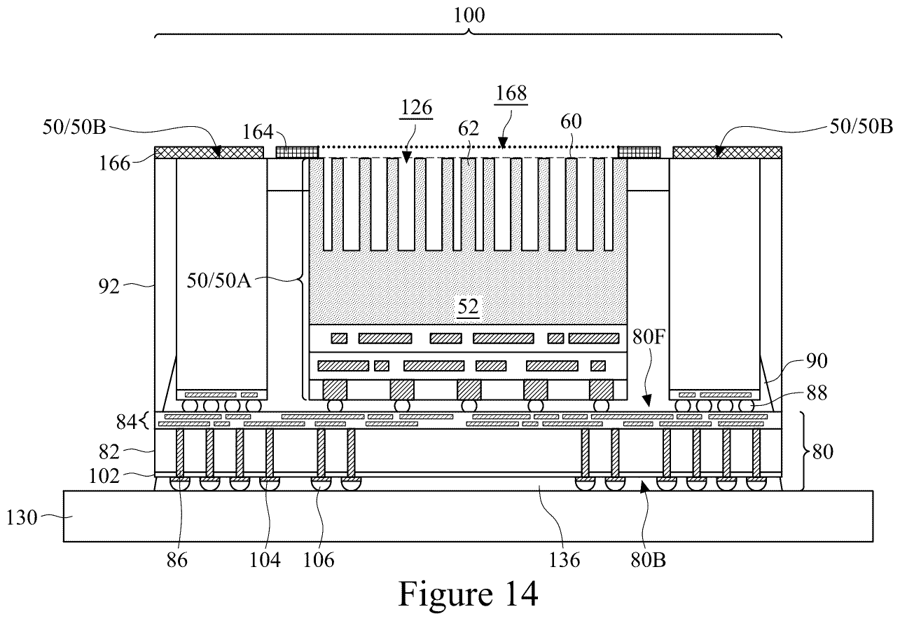

In FIG. 14, a sealant 164 is disposed over the first integrated circuit device 50A and the encapsulant 92, and an adhesive 166 is disposed over the second integrated circuit devices 50B, in accordance with some embodiments. For example, the sealant 164 may be disposed over the outer ring of the ribs 62 (e.g., the ring shape of the sealant 164 in a plan view in FIG. 1B and adjacent to the second integrated circuit devices 50B) and may extend over a portion of the encapsulant 92 between the first integrated circuit device 50A and the second integrated circuit device 50B. In some embodiments, the sealant 164 may partially or completely cover the top surface of the outer ring of the ribs 62. Accordingly, the sealant 164 may include a ring shape in a plan view. The sealant 164 may have sealing properties. For example, the sealant 164 includes silicone, epoxy, polytetrafluoroethylene (PTFE), polysulfide, polyurethane, suitable resins or rubbers, other suitable polymers, combinations thereof, or the like. The sealant 164 may have a sufficient width and thickness to prevent leakage of liquid metal.

The adhesive 166 is disposed over the second integrated circuit device 50B in accordance with some embodiments. The adhesive 166 may cover (e.g., in physical contact with) at least a portion of top surface of the second integrated circuit device 50B and may extend over the encapsulant 92. In some embodiments, the adhesive 166 further extends over a sidewall of the encapsulant 92. FIG. 14 shows the adhesive 166 being separated from the sealant 164, although the adhesive 166 may be in contact with the sealant 164 or even mixed with the sealant 164 in some embodiments. The adhesive 166 may have better adhesive and thermal conducting properties than the sealant 164, although the sealant 164 may have better sealing properties than the adhesive 166. In some embodiments, the adhesive 166 is a thermal interface material, such as a thermal conducting polymeric material (e.g., a polymer having a thermal conductivity of over 3 watts per meter kelvin (W/m·K)), solder paste, indium solder paste, or the like. In some embodiments, the adhesive 166 has a thickness similar to the thickness of the sealant 164. In some embodiments, the sealant 164 and the adhesive 166 are dispensed or applied on the integrated circuit devices 50 in a liquid form or a semi-liquid form and then cured together in a same curing process.

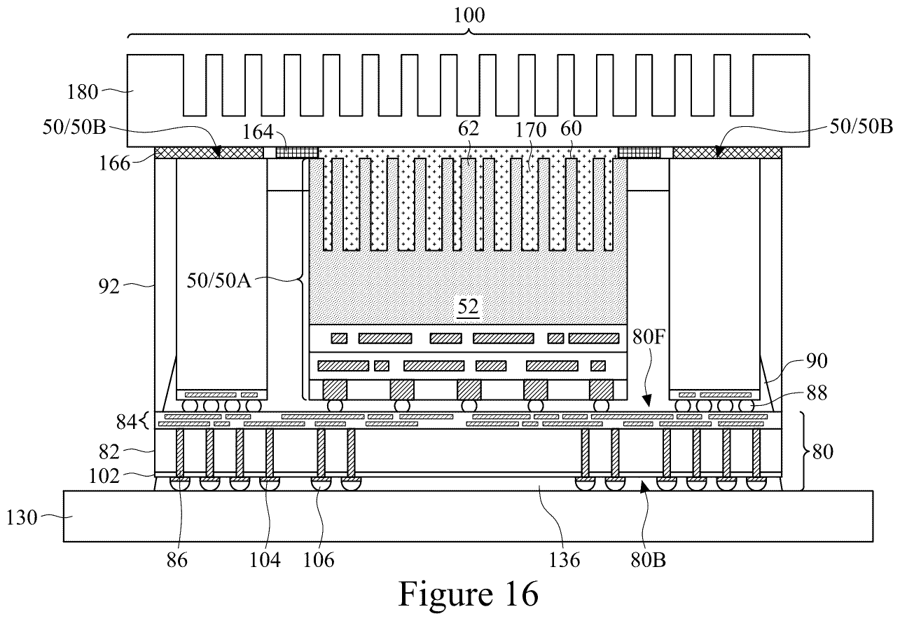

After the sealant 164 is applied, a space 168 is laterally enclosed by the sealant 164, such as laterally enclosed by the outer ring of the sealant 164, in accordance with some embodiments. In some embodiments, the space 168 is defined by side boundaries aligning with sidewalls of the sealant 164, a lower boundary (showing as a dash line in FIG. 14) level with the bottom surface of the sealant 164, and an upper boundary (showing as a dotted line in FIG. 14) level with an upper surface of the sealant 164 (or the bottom surface of heat sink 180 illustrated in FIG. 16). The channels 126 and the space 168 may be collectively referred to as a cavity hereinafter. A liquid metal 170 will be disposed into the cavity.

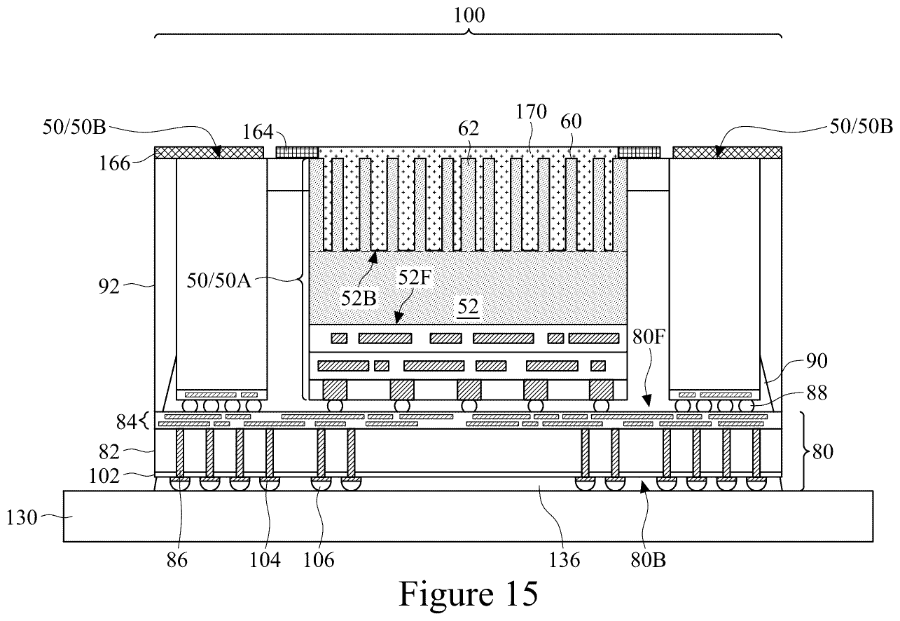

Referring to FIG. 15, after the sealant 164 and the adhesive 166 are formed, a liquid metal 170 is disposed into the cavity (e.g., channels 126 and the space 168 laterally enclosed by the sealant 164), in accordance with some embodiments. In some embodiments, the liquid metal 160 may be disposed in the cavity by injection. The liquid metal 170 may include a gallium-based material, such as gallium, an alloy of gallium and a metal consisting of a group selected from indium, tin, bismuth, nickel, and aluminum. Alternatively, the liquid metal 170 may include mercury, sodium-potassium eutectic alloy, bismuth-tin alloy, bismuth-lead alloy, a combination thereof, or the like. The liquid metal 170 has a high thermal conductivity, such as higher than the thermal interface material described for the adhesive 166. In addition, when the pillars 60 have a high aspect ratio and are in a dense arrangement for providing a large surface area, the liquid metal 170, which is in a liquid form, can easily flow into and substantially fill the channels 126 for conducting heat from the surfaces of the pillars 60. In some embodiments, the volume of the liquid metal 170 disposed into the channels 126 and the space 168 is predetermined by calculating the volume of the channels 126 and the space 168. Too much liquid metal 170 may cause overfill, and the liquid metal 170 may damage other components of the semiconductor package 100 since the liquid metal 170 may be corrosive. Too less liquid metal 170 may cause the liquid metal 170 in the channels 126 and/or the space 168 to have a gap with the heat sink (see FIG. 16), which would reduce the thermal conducting efficiency.

Referring to FIG. 16, a heat sink 180 is mounted on the intermediate structure as illustrated in FIG. 15, in accordance with some embodiments. The heat sink 180 may be adhered to the first integrated circuit device 50A, the second integrated circuit devices 50B, and the encapsulant 92 through the sealant 164 and the adhesive 166. In some embodiments, the heat sink 180 has a flat bottom surface. The heat sink 180 may be a solid metal or a solid metal alloy, such as aluminum, copper, nickel, cobalt, silver, titanium, iron, an alloy thereof, a combination thereof, or the like. The liquid metal 170 may be sealed and enclosed by the heat sink 180, the sealant 164, and the semiconductor substrate 52 of the first integrated circuit device 50A. Accordingly, in some embodiments, the liquid metal 170 is in physical contact with the pillars 60 and the ribs 62 of the semiconductor substrate 52, the second surface 52B of the semiconductor substrate 52, and the heat sink 180 so that the liquid metal 170 can exchange or conduct heat transfer between them. Since the pillars 60 have a large contact surface with the liquid metal 170, and the liquid metal 170 has good thermal conductivity, the heat generated by the first integrated circuit device 50A may efficiently be conducted to the heat sink 180 and dissipated away, which allows the semiconductor package 100 to be applied in fields of high-performance computing or other similar fields.

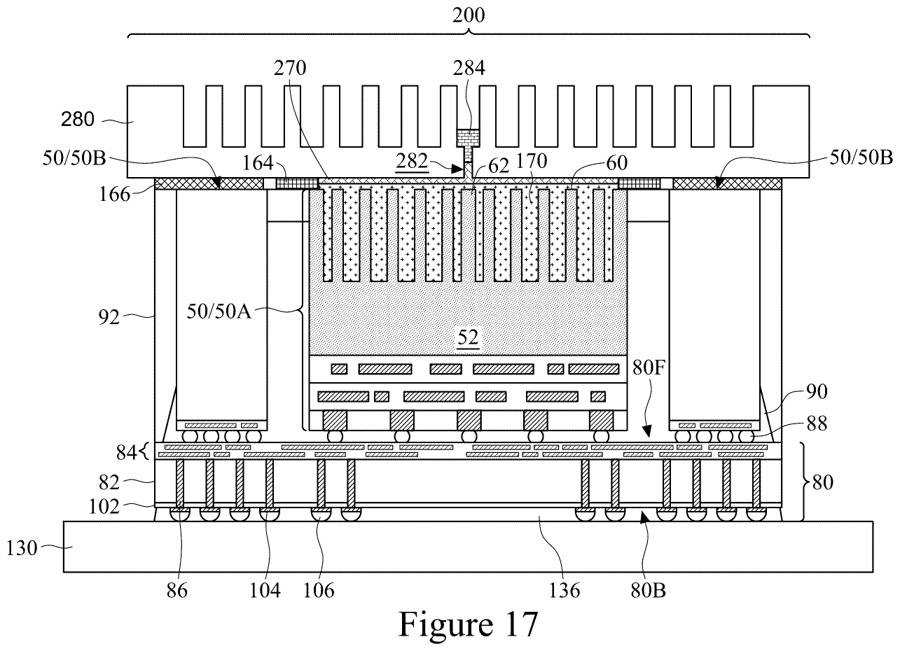

FIG. 17 illustrates a cross-sectional view of a semiconductor package 200 in accordance with some embodiments. The semiconductor package 200 is similar to the semiconductor package 100, where similar referencing numerals represent similar features. In some embodiments, the semiconductor package 200 includes the heat sink 280 mounted over the first integrated circuit device 50A, the second integrated circuit devices 50B, and the encapsulant 92 through the sealant 164 and the adhesive 166. The heat sink 280 may be similar to the heat sink 180 and further includes one or more holes 282 through the heat sink 280. As such, after the heat sink 180 is mounted, a liquid metal 270 may be additionally added into the space 168 and/or channels 126 through the hole 282. The liquid metal 270 may ensure that space 168 and channel 126 are substantially or completely filled with liquid metal. For example, the liquid metal 270 may be in physical contact with the heat sink 280 whether the liquid metal 170 contacts the heat sink 280.

In some embodiments, the liquid metal 270 is a same material as the liquid metal 170, although different liquid metal materials can be used. With using the heat sink 280, the step for disposing the liquid metal 170 into the cavity (e.g., the channels 126 and the space 168) described in FIG. 14 may include only partially filling the channels 126 and the space 168 with the liquid metal 170, and then adding the liquid metal 270 to substantially or completely fill the channels 126 and the space 168 after the heat sink 280 is mounted. In some embodiments, the liquid metal 270 also fills a lower portion of the hole 282. The liquid metal 270 may also possibly squeeze the liquid metal 170 into the hole 282. The level of the upper surface of the liquid metal 270 in the hole 282 illustrated in FIG. 17 is for illustration purposes only, and it can be adjusted by process requirements.

In some embodiments, when the liquid metal 170 is excess but not to the extent to cause overfill (e.g., not overfilling onto the sealant 164 because the liquid metal 170 is retained in the space 168 by surface tension) before mounting the heat sink 180, the hole 282 may provide room for containing the excess liquid metal 170, thereby reducing or preventing from the overfill problem. In such embodiments, while there is no need to add liquid metal 270, the liquid metal 170 may fill at least a lower portion of the hole 282.

In some embodiments, after the heat sink 280 is mounted and the cavity is substantially or completely filled with the liquid metal, a sealant 284 is applied to seal at least a top portion of the hole 282. The sealant 284 may be a material similar to the sealant 164, although the sealant 284 can be a material different from the sealant 164. In some embodiments, the sealant 284 includes silicone, epoxy, polytetrafluoroethylene (PTFE), polysulfide, polyurethane, suitable resins or rubbers, other suitable polymers, combinations thereof, or the like. In some embodiments, the sealant 284 is applied to the top portion of the hole 282 in a semi-liquid form and then cured by heat or UV light.

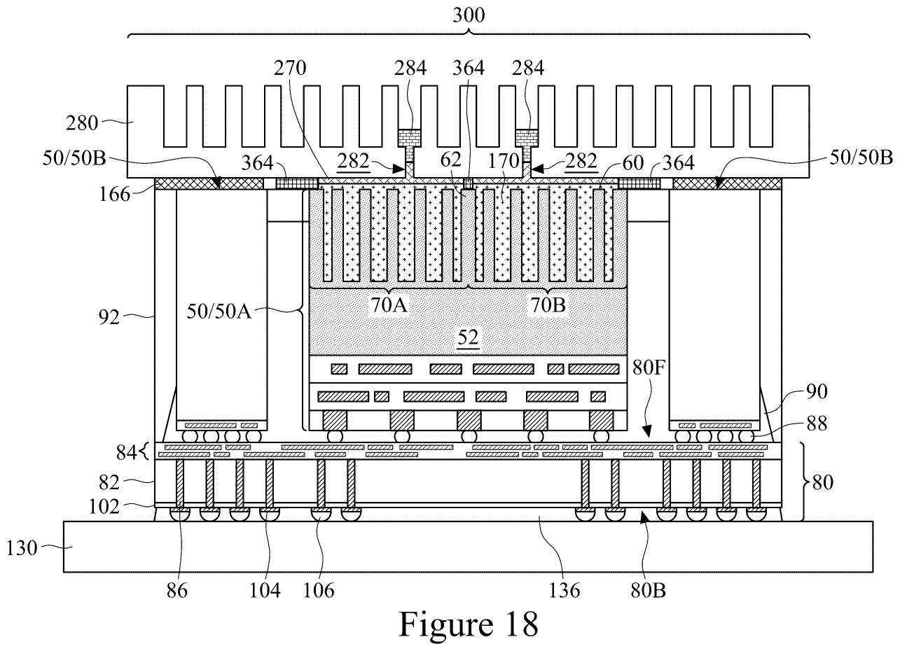

FIG. 18 illustrates a cross-sectional view of a semiconductor package 300 in accordance with some embodiments. The semiconductor package 300 is similar to the semiconductor package 100 or the semiconductor package 200, where similar referencing numerals represent similar features. In some embodiments, the semiconductor package 300 includes a sealant 364 similar to the sealant 164. The sealant 364 may be similar to the sealant 164 and may be formed in a same manner and formed of a similar material. In some embodiments, the sealant 364 has a shape corresponding to the shape of the ribs 62 in a plan view. For example, the sealant 364 may include a ring shape and a cross shape within the ring shape in a plan view when the ribs 62 include the shape as illustrated in FIG. 1B. Accordingly, after injecting the liquid metal 170 into the cavity and mounting the heat sink 180 (or heat sink 280), multiple chambers may be formed and separated from each other by the ribs 62 and the sealant. For example, in FIG. 18, a first chamber and a second chamber are formed in the sub-region 70A and the sub-region 70B, respectively, and the first chamber and the second chamber are separated by the ribs 62 and the sealant 364. Accordingly, the liquid metal 170 in each of the subregions 70A-70D is confined and sealed in their respective sub-regions 70A-70D. Because the liquid metal 170 in the sub-regions 70A-70D are confined and sealed, if the liquid metal 170 in one of the sub-regions 70A-70D is leaked, the liquid metal 170 in the remaining ones of the sub-regions 70A-70D may still be confined and does not leak. Thus, the potential damage and the decline of thermal dissipation performance may be managed or minimized. In some embodiments, since the liquid metal 170 in the sub-regions 70A-70D are individually confined, the heat sink 280 includes holes 282 connecting to the respective sub-regions 70A-70D for allowing to provide additional liquid metal 270 or to contain the excess liquid metal 170 in the sub-regions 70A-70D.

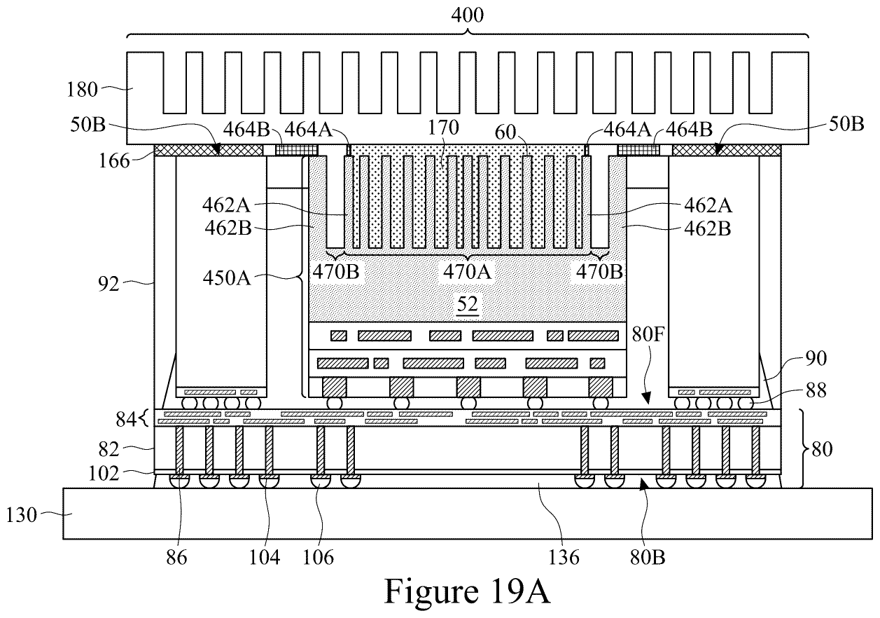

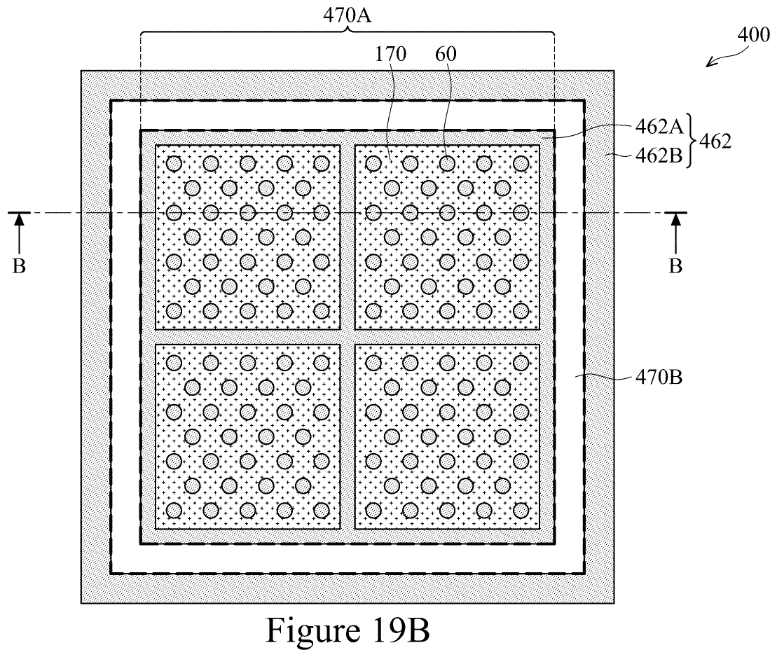

FIG. 19A illustrates a cross-sectional view of a semiconductor package 400 including an integrated circuit device 450A, and FIG. 19B is a plan view of the integrated circuit device 450A with the liquid metal 170, wherein the integrated circuit device 450A and the liquid metal 170 in FIG. 19B are taken along the B-B line in FIG. 19A. The semiconductor package 400 and the integrated circuit device 450A may be similar to the semiconductor packages 100-300 and the first integrated circuit device 50A, respectively, and where similar referencing numerals represent similar features. In semiconductor package 400, an empty trench is used to prevent or reduce the leakage of the liquid metal 170 and/or the liquid metal 270 (not separately illustrated in FIG. 19A).

Referring to FIG. 19B, the first integrated circuit device 50A includes ribs 462 and pillars 60 at the back side of the semiconductor substrate 52, in accordance with some embodiments. The ribs 462 are similar to the ribs 62. In some embodiments, some of the ribs 462 form an inner ring 462A, and some of the ribs 462 form an outer ring 462B. The inner ring 462A is surrounded by the outer ring 462B and has a gap with the outer ring 462B. In some embodiments, the sealant 464 may have a shape corresponding to the shape of the ribs 462 in the plan view, such that the sealant 464 and the ribs 462 may divide the back side of the semiconductor substrate 52 into multiple individual sub-regions. For example, the sealant 464 may include an inner ring 464A disposed on the inner ring 462A of the ribs 462, and the outer ring 464B may be disposed on the outer ring 462B of the ribs 462. In some embodiments, the inner ring 462A of the ribs 462 and the inner ring 464A of the sealant 464 divide may divide the back side of the semiconductor substrate 52 into an inner region 470A and an outer region 470B, wherein the outer region 470B is between the inner rings 462A and 464A and the outer rings 462B and 464B.

In some embodiments, the liquid metal 170 may be only disposed into the inner region 470A but leave the outer region 470B empty. As such, if the liquid metal 170 in the inner region 470A is leaked, the channel 126 in the outer region 470B may be an empty trench for providing a buffer to store the liquid metal 170 when the liquid metal 170 is leaked from the inner region 470A. Accordingly, because a mechanism for preventing or reducing the leakage of the liquid metal is provided, the damage resulting from the leakage of liquid metal may be reduced or prevented, and the reliability of the semiconductor package 400 is improved. Although FIGS. 19A and 19B illustrate the outer region 470B as a one-ring-shaped trench, more ring-shaped trenches may be used. In some embodiments, although not shown in FIG. 19B, the heat sink in the semiconductor package 400 may include one or more holes 282 through the heat sink 180 and connect to the inner region 470A, and the heat sink 180 may not include a hole connecting to the outer region 470B.

According to various embodiments, a semiconductor package includes a liquid metal disposed over integrated circuit devices for dissipating heat. In some embodiments, the integrated circuit device includes pillars of high aspect ratio at its back side, for providing a large contact area with the liquid metal. As such, the high contact area and the excellent thermal conductivity of the liquid metal may provide the semiconductor package with improved thermal dissipation performance. In some embodiments, the semiconductor package also includes one or more holes in a heat sink mounted over the integrated circuit device, which allows more liquid metal to be added into the semiconductor package or contain excess liquid metal. In some embodiments, the semiconductor package includes an empty trench for storing leaked liquid metal, thereby providing an additional mechanism to prevent the leakage of liquid metal.

In one aspect, embodiments disclosed herein provide for a semiconductor package including a first integrated circuit device, wherein the first integrated circuit device comprises a semiconductor substrate and an interconnect structure disposed over a first surface of the semiconductor substrate, wherein the semiconductor substrate comprises pillars protruding from a second surface of the semiconductor substrate. The package also include a heat sink disposed over the first integrated circuit device, wherein the heat sink, and the pillars, enclose a space, and a liquid metal disposed in a space between the pillars.

In another aspect, embodiments disclosed herein provide for a semiconductor package, including an integrated circuit device attached to a substrate, wherein the integrated circuit device comprises a semiconductor substrate having an active surface facing the substrate, a first sealant disposed over the integrated circuit device, a heat sink disposed over the sealant, wherein the heat sink comprises a hole through the heat sink, a second sealant at least sealing the hole, wherein the heat sink, the first sealant, the second sealant, and the semiconductor substrate enclose a cavity, and a liquid metal disposed in the cavity.

In yet another aspect, embodiments disclosed herein provide for a method for forming a package, the method including forming an encapsulant laterally surrounding an integrated circuit device, wherein the integrated circuit device comprises a semiconductor substrate and an interconnect structure attached to a first surface of the semiconductor substrate, wherein the semiconductor substrate comprises pillars and ribs protruding from a second surface of the semiconductor substrate, the second surface being opposite to the first surface, applying a first sealant over the integrated circuit device, wherein the first sealant comprises a ring shape in a plan view, injecting a first liquid metal to between the pillars and the ribs and a space laterally enclosed by the ring shape of the first sealant, and mounting a heat sink over the first sealant and the integrated circuit device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor package, comprising:
a first integrated circuit device, wherein the first integrated circuit device comprises a semiconductor substrate and an interconnect structure disposed over a first surface of the semiconductor substrate, wherein the semiconductor substrate comprises pillars protruding from a second surface of the semiconductor substrate;
a heat sink disposed over the first integrated circuit device, wherein the heat sink, and the pillars, enclose a space; and
a liquid metal disposed in a space between the pillars.

2. The semiconductor package of claim 1, wherein the liquid metal comprises a gallium-based material, mercury, sodium-potassium eutectic alloy, bismuth-tin alloy, bismuth-lead alloy, or a combination thereof.

3. The semiconductor package of claim 1, wherein at least one of the pillars is laterally surrounded by ribs protruding from the second surface of the semiconductor substrate, and further comprising an encapsulant laterally surrounding the at least one of the pillars and the ribs, wherein respective top surfaces of the at least one of the pillars and the ribs are coplanar with a top surface of the encapsulant.

4. The semiconductor package of claim 1, wherein the liquid metal is in physical contact with the heat sink and the second surface of the semiconductor substrate.

5. The semiconductor package of claim 3, wherein the liquid metal covers top surfaces of the pillars and the top surfaces of the ribs.

6. The semiconductor package of claim 3, further comprising a sealant disposed over the first integrated circuit device and further wherein the sealant has a shape corresponding to a shape of the ribs in a plan view.

7. The semiconductor package of claim 1, further comprising a second integrated circuit device, an encapsulant laterally surrounding the first integrated circuit device and the second integrated circuit device, a sealant disposed over the first integrated circuit device, and an adhesive disposed between the heat sink and the second integrated circuit device, wherein the adhesive has a higher thermal conductivity than the sealant.

8. A semiconductor package, comprising:
an integrated circuit device attached to a substrate, wherein the integrated circuit device comprises a semiconductor substrate having an active surface facing the substrate;
a first sealant disposed over the integrated circuit device;
a heat sink disposed over the first sealant, wherein the heat sink comprises a hole through the heat sink;
a second sealant at least sealing the hole, wherein the heat sink, the first sealant, the second sealant, and the semiconductor substrate enclose a cavity; and
a liquid metal disposed in the cavity.

9. The semiconductor package of claim 8, wherein the liquid metal extends into the hole.

10. The semiconductor package of claim 8, wherein the semiconductor substrate comprises a surface opposite to the active surface, pillars protruding over the surface, and ribs protruding over the surface, wherein a top surface of at least one of the pillars and a top surface of at least one of the ribs are coplanar.

11. The semiconductor package of claim 10, wherein the first sealant has a shape corresponding to a shape of the ribs in a plan view, and the first sealant and the ribs divide the cavity into a first chamber and a second chamber, wherein at least one of the pillars is in the first chamber, and at least one of the pillars is in the second chamber.

12. The semiconductor package of claim 11, wherein the hole of the heat sink comprises a first hole laterally aligned to the first chamber and a second hole laterally aligned to the second chamber.

13. The semiconductor package of claim 10, wherein the liquid metal is in physical contact with top surfaces of the pillars, the top surfaces of the ribs, and a bottom surface of heat sink.

14. The semiconductor package of claim 8, wherein the first sealant further comprises a cross shape plan view.

15. A method for forming a package, the method comprising:
forming an encapsulant laterally surrounding an integrated circuit device, wherein the integrated circuit device comprises a semiconductor substrate and an interconnect structure attached to a first surface of the semiconductor substrate, wherein the semiconductor substrate comprises pillars and ribs protruding from a second surface of the semiconductor substrate, the second surface being opposite to the first surface;
applying a first sealant over the integrated circuit device, wherein the first sealant comprises a ring shape in a plan view;
injecting a first liquid metal between the pillars and the ribs and a space laterally enclosed by the ring shape of the first sealant; and
mounting a heat sink over the first sealant and the integrated circuit device.

16. The method of claim 15, wherein the first liquid metal is in physical contact with the heat sink.

17. The method of claim 15, wherein the heat sink comprises a hole through the heat sink, and the method comprises sealing at least a top portion of the hole with a second sealant.

18. The method of claim 17, further comprising injecting a second liquid metal into the hole after mounting the heat sink.

19. The method of claim 18, wherein the second liquid metal is a same material as the first liquid metal.

20. The method of claim 15, further comprising:
disposing dummy features between the pillars and the ribs before forming the encapsulant;
after disposing the dummy features and before forming the encapsulant, attaching the integrated circuit device to an interposer;
thinning the encapsulant to expose the dummy features; and
removing the dummy features after the dummy features are exposed.
